(19) United States
(12) Patent Application Publication
(10) Pub. No.: US 2002/0081772 A1
(43) Pub. Date: Jun. 27, 2002

(54) Method and system for manufacturing ball grid array ("BGA") packages

(76) Inventors: Ruben P. Madrid, Baguio City (PH); Diosdado Palacpac, Baguio City (PH)

Correspondence Address: TEXAS INSTRUMENTS INCORPORATED, P O BOX 655474, M/S 3999, DALLAS, TX, 75265

(21) Appl. No.: 10/002,724

(22) Filed: Oct. 25, 2001

Related U.S. Application Data
(60) Provisional application No. 60/257,939, filed on Dec. 21, 2000.

(51) Int. Cl. H01L 21/44; H01L 21/48; H01L 21/50

(52) U.S. Cl. 438/108; 438/113

(57) ABSTRACT

According to one embodiment of the invention, a method for manufacturing a ball grid array package includes providing a flip chip, coupling the flip chip to a first side of a substrate, encapsulating the flip chip with a molding, attaching a plurality of solder balls to a second side of the substrate, and cutting the substrate to produce the ball grid array package.

### TECHNICAL FIELD OF THE INVENTION

This invention relates generally to the field of integrated circuits and, more specifically, to a method and system for manufacturing ball grid array packages.

### BACKGROUND OF THE INVENTION

There are many different types of integrated circuit packages and many different techniques for manufacturing integrated circuit packages. For example, one type of integrated circuit package is a ball grid array package manufactured using a “flipped-chip” technique. A “flipped-chip” technique is where an integrated circuit die has solder bumps attached to one side of the die and then the die is “flipped over” and attached to a printed circuit board or other substrate having solder pads. The dies with the solder bumps are sometimes referred to as “flip chips.” Ball grid array packages made with flip chips are referred to as flipped-chip ball grid arrays (“FCBGAs”), and are desirable because, among other attributes, they save valuable printed circuit board space. Because of the desirable attributes of FC-BGAs, integrated circuit package manufacturers desire to find reliable and cost-effective ways to manufacture FC-BGAs.

One method of manufacturing FC-BGAs includes forming flip chips, individually attaching the flip chips to a substrate, hermetically (or non-hermetically) sealing the flip chips by attaching an enclosure lid to the substrate that encloses the flip chip, and attaching solder bumps to the other side of the substrate. Because of the use of enclosure lids and because dies are handled individually, considerable time and money is wasted.

### SUMMARY OF THE INVENTION

Because of the ever-increasing use of integrated circuits, manufacturers are continually searching for better and more economical ways of manufacturing ball grid array packages. Therefore, a need has arisen for a new method and system for manufacturing ball grid array packages.

In accordance with the present invention, a method and system for manufacturing ball grid array packages is provided that addresses disadvantages and problems associated with previously developed methods and systems.

According to one embodiment of the invention, a method for manufacturing a ball grid array package includes providing a flip chip, coupling the flip chip to a first side of a substrate, encapsulating the flip chip with a molding, attaching a plurality of solder balls to a second side of the substrate, and cutting the substrate to produce the ball grid array package.

According to another embodiment of the invention, a system for manufacturing a plurality of ball grid array packages includes a substrate having a first side and a second side, a plurality of flip chips coupled to the first side of the substrate, a molding encapsulating the flip chips, a plurality of solder balls coupled to the second side of the substrate, and a cutting machine operable to singulate the ball grid array packages by cutting the substrate.

Embodiments of the invention provide numerous technical advantages. For example, a technical advantage of one embodiment of the present invention is that enclosure lids for flip chips are eliminated, thereby saving time and expense. In addition, the use of a molding in place of an enclosure lid enhances reliability by increasing the thermal cycle lifetime of a BGA package. Another technical advantage of one embodiment of the present invention is that multiple BGAs can be formed simultaneously by utilizing a transfer molding process to encapsulate multiple flip chips with a molding. Combining this molding process with an ability to singulate all of the BGA packages with only two passes of a plurality of cutting blades results in considerable time and money savings.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIG. 1 is a half-sectional perspective view of one embodiment of a ball grid array package manufactured according to the teachings of the present invention;

FIG. 2 is a plan view illustrating a semiconductor wafer having a plurality of integrated circuit dies formed thereon being scribed or cut by a plurality of cutting blades according to one embodiment of the present invention;

FIG. 3 is an elevation view illustrating a plurality of flip chips coupled to a substrate according to one embodiment of the present invention;

FIG. 4 is an elevation view illustrating the plurality of flip chips of FIG. 3 being underfilled according to one embodiment of the present invention;

FIG. 5 is an elevation view illustrating the plurality of flip chips of FIG. 3 being encapsulated in a molding according to one embodiment of the present invention;

FIG. 6 is an elevation view illustrating a plurality of solder balls being coupled to the substrate of FIG. 3 according to one embodiment of the present invention;

FIG. 7 is an elevation view illustrating a plurality of ball grid array packages being singulated by a plurality of cutting blades according to one embodiment of the present invention; and

FIG. 8 is an elevation view illustrating the plurality of ball grid array packages of FIG. 7 being transferred to a shipping tray according to one embodiment of the present invention.

### DETAILED DESCRIPTION OF EXAMPLE EMBODIMENTS OF THE INVENTION

Example embodiments of the present invention and their advantages are best understood by referring now to FIGS. 1-8 of the drawings, in which like numerals refer to like parts.

FIG. 1 is a half-sectional perspective view of one embodiment of a ball grid array (“BGA”) package 100 manufactured according to the teachings of the present invention. Integrated circuit manufacturers fabricate BGA packages in different ways. One way of manufacturing a BGA package is to use a “flipped-chip” technique. A “flipped-chip” technique is where an integrated circuit die has solder bumps attached to one side thereof and the die is “flipped” over and attached to a printed circuit board or other substrate having solder pads. The die with the solder bumps is sometimes referred to as a flip chip. The flip chip and the substrate are then subjected to heat so the solder bumps can form a strong bond with the solder pads on the substrate. After an underfill is applied to fill the voids between the flip chip and the substrate, an enclosure lid is placed over the flip chip and attached to the substrate to protect the flip chip during operation. Solder balls are then attached to the underside of the substrate and reflow technology is used to ensure strong bonds between the solder balls and the substrate thereby completing the manufacture of the BGA package.

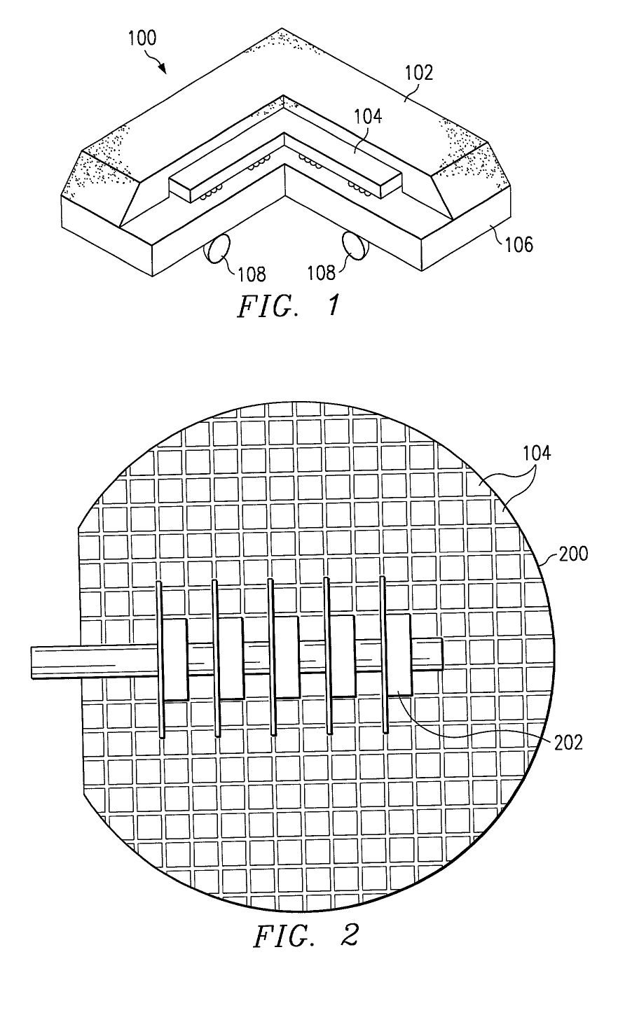

Because of the use of enclosure lids and because previous BGA packages are handled individually, considerable time and money is wasted. The present invention addresses these problems, and others, by providing BGA package 100 that includes a molding 102 encapsulating an integrated circuit die 104 that is coupled to a substrate 106 as shown in FIG. 1. BGA package 100 also includes solder balls 108 coupled to an underside of substrate 106. One method of manufacturing BGA package 100 is described below in detail in conjunction with FIGS. 2-8.

FIG. 2 is a plan view illustrating a semiconductor wafer 200 being separated into a plurality of integrated circuit dies 104 by a plurality of cutting blades 202. In one embodiment, semiconductor wafer 200 is a 300 millimeter diameter wafer made of silicon; however, semiconductor wafer 200 may have other diameters and may be formed from other suitable types of semiconductor material, such as germanium. Semiconductor wafer 200 may also be formed with any suitable thickness. The function of semiconductor wafer 200 is to serve as a medium for the fabrication of integrated circuit dies 104. Integrated circuit dies 104 may have any combination of doped or undoped layers or regions, dielectric layers or regions, and metallization patterns that form an integrated circuit.

Cutting blades 202 are operable to scribe, saw, or cut semiconductor wafer 200 to facilitate separating individual circuit dies 104. There may be one or any number of cutting blades 202, and cutting blades 202 may be controlled through any suitable manual or automated process. An individual cutting blade 202, in one embodiment, is a rotary blade formed from diamond particles suspended in a resin or nickel matrix; however, cutting blade 202 may be any type of cutting blade suitable for separating semiconductor wafer 200.

In one embodiment of the present invention, cutting blades 202 scribe lines perpendicular to each other in semiconductor wafer 200 to define a plurality of integrated circuit dies 104. Scribing means that all of the integrated circuit dies 104 on semiconductor wafer 200 are still connected to each other. Scribing includes dragging a diamond tipped scribe through the center of scribe lines on semiconductor wafer 200. The scribe creates a shallow scratch in the surface of semiconductor wafer 200. In another embodiment, cutting blades 202 penetrate all the way through the thickness of semiconductor wafer 200, thereby separating all of integrated circuit dies 104 that are fabricated on semiconductor wafer 200.

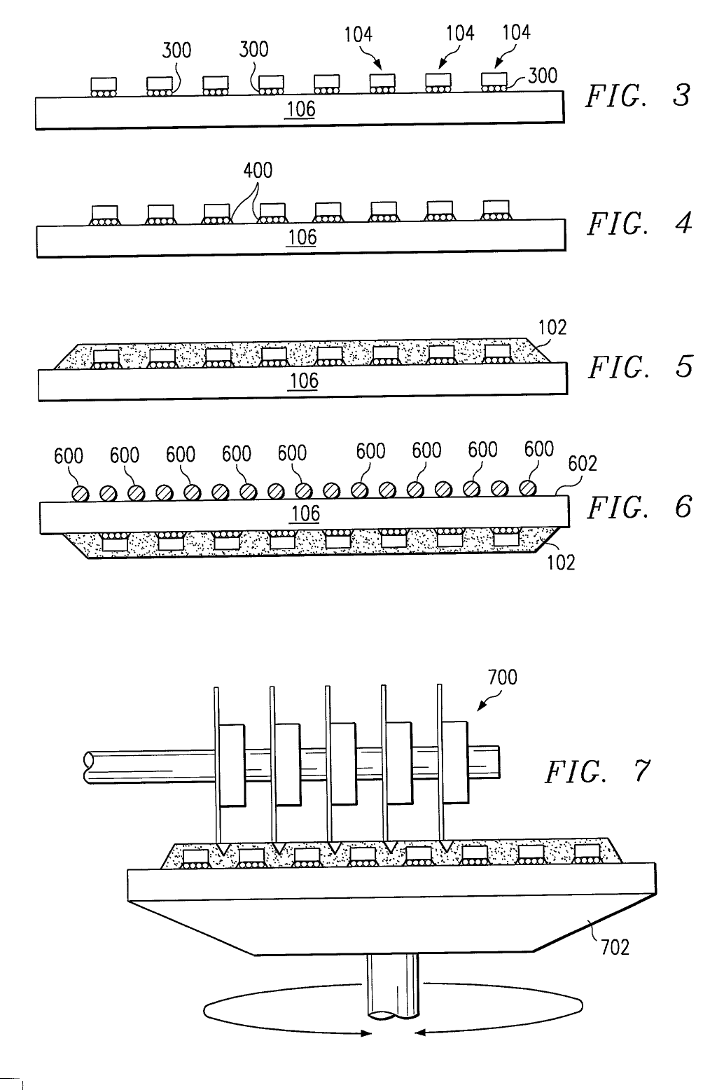

After integrated circuit dies 104 are defined on semiconductor wafer 200, integrated circuit dies 104 are transferred to substrate 106. The transfer may be done manually or automatically using any suitable pick-and-place machine well known in the art of semiconductor processing. In a manual method, an operator picks up each of integrated circuit dies 104 with, for example, a vacuum wand and places it in its desired location. In an automated method, a robot using machine vision technology and having the ability to be programmed to perform certain functions directs a vacuum wand to pick up integrated circuit dies 104 and transfer them to their desired location. After transferring integrated circuit dies 104 to substrate 106, integrated circuit dies 104 are coupled to substrate 106 as described below in conjunction with FIG. 3.

FIG. 3 is an elevation view illustrating a plurality of integrated circuit dies 104 coupled to substrate 106 according to one embodiment of the present invention. In one embodiment, integrated circuit dies 104 are coupled to substrate 106 using flipped-chip technology. In this embodiment, integrated circuit dies 104 have a plurality of solder bumps 300 coupled to one side of integrated circuit dies 104. Solder bumps 300 are formed on integrated circuit die 104 so that solder bumps 300 match up with a plurality of solder pads (not explicitly shown in FIG. 3) on substrate 106 for attachment. Standard reflow technology, which is well known in the art of semiconductor manufacturing, is then used to melt solder bumps 300 so that strong bonds are formed with the solder pads on substrate 106. Integrated circuit dies 104 may be attached to substrate 106 using other suitable methods.

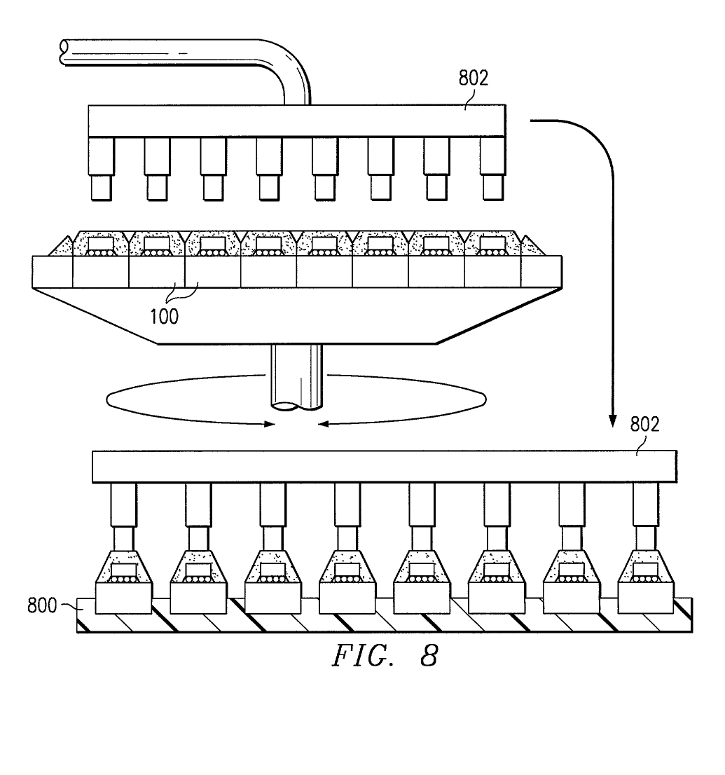

Substrate 106, in one embodiment, is a glass-fiber-reinforced epoxy resin such as FR4; however, substrate 106 may be formed from other suitable materials. In addition, substrate 106 may be thinner substrates, such as polyimide or a ceramic film substrate for high temperature applications, or thicker substrates, such as a multilayer (i.e., a laminate) substrate. In one embodiment, substrate 106 is rectangularly shaped with dimensions approximately 10 inches wide by 12 inches long; however, substrate 106 can have any suitable shape and can by any suitable size. Although not shown in any of the figures for clarity purposes, substrate 106 has one or more conductive paths formed therein to electrically connect integrated circuit dies 104 to a plurality of solder balls 600 (FIG. 6) coupled to substrate 106. After coupling integrated circuit dies 104 to substrate 106, voids exist between integrated circuit die 104 and substrate 106 because of the use of solder bumps 300. These voids typically have to be filled using an underfill technique as described below in conjunction with FIG. 4.

FIG. 4 is an elevation view illustrating integrated circuit dies 104 underfilled with an underfill material 400 according to one embodiment of the present invention. In one embodiment, underfill material 400 is an epoxy; however, underfill material 400 may be other types of materials suitable for filling in the voids that exist between integrated circuit die 104 and substrate 106. Underfill material 400 is used to enhance the bond of integrated circuit die 104 to substrate 106 and to provide better reliability by reducing the stresses from the joining of solder bumps 300 to the solder pads on substrate 106. Better reliability of BGA package 100 is also obtained because underfill material 400 increases the thermal cycle lifetime of BGA package 100. After underfill material 400 is applied, integrated circuit dies 104 are ready to be encapsulated by molding 102 as described below in conjunction with FIG. 5.

FIG. 5 is an elevation view illustrating integrated circuit dies 104 encapsulated by molding 102 in accordance with one embodiment of the present invention. Molding 102, in one embodiment, is an epoxy material; however, molding 102 may be other types of thermosetting plastics, thermoplastics, or other types of materials suitable for encapsulating integrated circuit dies 104 and protecting integrated circuit die 104 from contaminants and harsh environments. In one embodiment, molding 102 encapsulates substantially all of integrated circuit dies 104 utilizing a transfer molding process. A transfer molding process is able to achieve high dimensional control and its suitable for complex parts. It should be understood, however, that other types of processes may be used to apply molding 102 to substrate 106 for the purpose of encapsulating integrated circuit dies 104.

One technical advantage of the present invention is that molding 102 is used to encase integrated circuit dies 104 instead of enclosure lids that were used in previous methods. The use of these enclosure lids wasted considerable time and money. In addition, these enclosure lids were attached one at a time to a substrate to enclose integrated circuit dies. Molding 102 saves considerable time and money in manufacturing BGA package 100 in that multiple integrated circuit dies 104 can be overmolded at once. Molding 102, depending on the type of material used, may also have the ability to underfill the voids between integrated circuit dies 104 and substrate 106 in lieu of underfill material 400 as described above in conjunction with FIG. 4. This further reduces the amount of time for manufacturing BGA package 100 and, hence, further reduces manufacturing costs. After integrated circuit dies 104 are encapsulated with molding 102, solder balls 600 are attached to a second side 602 of substrate 106 as described below in FIG. 6.

FIG. 6 is an elevation view illustrating solder balls 600 coupled to a second side 602 of substrate 106 according to one embodiment of the present invention. In one embodiment, solder balls 600 are 0.5 millimeter diameter metal solder balls made of a combination of tin and lead; however, solder balls 600 may be formed with other suitable diameters and may be formed from other suitable types of materials. In one embodiment, solder balls 600 are spaced at a pitch of 0.8 millimeters; however, other suitable types of pitches may be used. Reflow technology may be employed after coupling solder balls 600 to substrate 106 to ensure strong bonds between solder balls 600 and substrate 106. As described above in conjunction with FIG. 3, substrate 106 has one or more conductive paths formed therein to electrically connect integrated circuit dies 104 to solder balls 600. These conductive paths and/or other conductive regions are not shown in FIG. 6 for clarity purposes. To complete manufacturing of BGA packages 100, BGA packages 100 have to be singulated as shown in FIG. 7.

FIG. 7 is an elevation view illustrating the singulation of BGA packages 100 by a plurality of cutting blades 700 according to one embodiment of the present invention. A singulation process is used where BGA packages 100 are mass produced on a single substrate, such as the ganged-type production of BGA packages 100 on substrate 106 as shown in FIGS. 2-7. A singulation process is typically performed with cutting blades 700 that have rotary blades formed from diamond particles suspended in a resin or nickel matrix. However, cutting blades 700 may be other types of cutting machines, such as die punches, saws, thermal-sonic knives, water jets, or lasers. There may be one or any number of cutting blades 700. Cutting blades 700 may or may not be the same as cutting blades 202 as described above in conjunction with FIG. 2.

In one embodiment, cutting blades 700 are used to singulate BGA packages 100 in two steps. The first step is to use a plurality of cutting blades 700 to scribe or cut molding 102 and substrate 106 in one direction. This results in a number of rows of BGA packages 100. In the example shown in FIG. 7, this means that there needs to be a total of seven cutting blades 700 to obtain eight rows. After scribing or cutting molding 102 and substrate 106 in one direction, substrate 106, which may be placed on a rotatable worktable 702, is then rotated at substantially 90 degrees to its original location. Then cutting blade 700 scribes or cuts the rows of BGA packages 100 to obtain individual BGA packages 100. The process described results in a technical advantage of one embodiment of the present invention in that using a plurality of cutting blades 700 speeds up the singulation process, thereby improving the sprint parts per hour of the BGA package 100 manufacturing process. After BGA packages 100 are completed, BGA packages may be prepared for shipment by transferring them to a shipping tray 800 as shown and described in conjunction with FIG. 8.

FIG. 8 is an elevation view illustrating BGA packages 100 being transferred to shipping tray 800 according to one embodiment of the present invention. In one embodiment, shipping tray 800 is a standard Joint Electronic Device Engineering Council (“JEDEC”) tray, however, shipping tray 800 may be any type of shipping tray suitable for shipping BGA packages 100. As shown in FIG. 8, BGA packages 100 may be transferred to shipping tray 800 using one or more vacuum wands 802, which are well known in the art of integrated circuit package manufacturing. The transfer of BGA packages 100 may be accomplished either manually or automatically.

Although embodiments of the invention and their advantages are described in detail, a person skilled in the art could make various alternations, additions, and omissions without departing from the spirit and scope of the present invention as defined by the appended claims.

What is claimed is:

1. A method for manufacturing a ball grid array package, comprising:
providing a flip chip;
coupling the flip chip to a first side of a substrate;
encapsulating the flip chip with a molding;
attaching a plurality of solder balls to a second side of the substrate;
and
cutting the substrate to produce the ball grid array package.

2. The method of claim 1, further comprising transferring the ball grid array package to a shipping tray.

3. The method of claim 1, wherein providing the flip chip comprises forming an integrated circuit die on a wafer, scribing the wafer to define edges of the flip chip, and coupling a plurality of solder bumps to the integrated circuit die.

4. The method of claim 1, wherein coupling the flip chip to the first side of the substrate comprises soldering a plurality of solder bumps coupled to the flip chip to a plurality of solder pads on the first side of the substrate.

5. The method of claim 1, wherein encapsulating the flip chip with the molding comprises encapsulating the flip chip by utilizing a transfer molding process.

6. The method of claim 1, wherein encapsulating the flip chip with the molding comprises encapsulating the flip chip with an epoxy.

7. The method of claim 1, wherein cutting the substrate comprises:
cutting the substrate in a first direction; and
after cutting the substrate in the first direction, cutting the substrate in a second direction substantially perpendicular to the first direction.

8. A method for manufacturing a plurality of ball grid array packages, comprising:
providing a plurality of flip chips;
coupling the flip chips to a first side of a substrate;
encapsulating the flip chips with a molding;
attaching a plurality of solder balls to a second side of the substrate;
and
cutting the substrate to produce the ball grid array packages.

9. The method of claim 8, wherein providing the plurality of flip chips comprises forming a plurality of integrated circuit dies on a wafer, scribing the wafer to define edges of the integrated circuit dies, and coupling a plurality of solder bumps to the integrated circuit dies.

10. The method of claim 8, coupling the flip chip to the first side of the substrate comprises soldering a plurality of solder bumps coupled to the flip chip to a plurality of solder pads on the first side of the substrate.

11. The method of claim 8, wherein encapsulating the flip chips with the molding comprises encapsulating substantially all of the flip chips by utilizing a transfer molding process.

12. The method of claim 8, wherein encapsulating the flips chips with the molding comprises encapsulating the flip chips with an epoxy.

13. The method of claim 8, wherein cutting the substrate to produce the ball grid array packages comprises:
cutting the substrate in a first direction with a plurality of cutting blades;
rotating the substrate substantially 90 degrees with respect to the cutting blades; and
cutting the substrate in a second direction substantially 90 degrees to the first direction.

14. A system for manufacturing a plurality of ball grid array packages, comprising:
a substrate having a first side and a second side;
a plurality of flip chips coupled to the first side of the substrate;
a molding encapsulating the flip chips;
a plurality of solder balls coupled to the second side of the substrate;
and
a cutting machine operable to singulate the ball grid array packages by cutting the substrate.

15. The system of claim 14, further comprising a shipping tray operable to accept the ball grid array packages for shipping.

16. The system of claim 14, wherein the plurality of flip chips comprises a plurality of integrated circuit dies formed on a wafer, and a plurality of solder bumps coupled to the integrated circuit dies.

17. The system of claim 14, wherein the plurality of flip chips are coupled to the first side of the substrate by soldering a plurality of solder bumps on the flip chips to a plurality of solder pads on the first side of the substrate.

18. The system of claim 14, wherein the molding is an epoxy.

19. The system of claim 14, wherein the cutting machine comprises a plurality of cutting blades.

20. The system of claim 14, further comprising a work table operable to rotate the substrate at least substantially 90 degrees.
